(19) United States
(12) Patent Application Publication
(10) Pub. No.: US 2012/0063210 A1
(43) Pub. Date: Mar. 15, 2012

(54) Semiconductor Device

(75) Inventor: Osamu Hirabayashi, Tokyo (JP)

(73) Assignee: KABUSHIKI KAISHA TOSHIBA, Tokyo (JP)

(21) Appl. No.: 13/230,120

(22) Filed: Sep. 12, 2011

(30) Foreign Application Priority Data
Sep. 10, 2010 (JP) P2010-203614

(51) Int. Cl. G11C 11/00

(52) U.S. Cl. 365/154

(57) ABSTRACT

Provided is a semiconductor device including an SRAM memory cell that includes: a first inverter and a second inverter that are connected to a single power-supply node and are cross-coupled to each other; a first transfer transistor; and a second transfer transistor. A predetermined voltage is applied from a voltage generation unit to a source terminal of an NMOS transistor included in the first inverter. An inversion detection unit is connected to the SRAM memory cell via the first and second transfer transistors. When a word-line selection potential is applied to a word line with the SRAM memory cell having data written therein, the inversion detection unit detects whether or not the data written in the SRAM memory cell is inverted. In accordance with the detection result of the inversion detection unit, a word-line selection-potential determination unit controls the word-line selection potential to be applied to the word line.

### CROSS-REFERENCE TO RELATED APPLICATIONS

This Application is based upon and claims the benefit of priority from the prior Japanese Patent Application No. P2010-203614, filed on Sep. 10, 2010; the entire contents of which are incorporated herein by reference.

### FIELD

Embodiments described herein relate generally to a semiconductor device.

### BACKGROUND

In order to make a static random access memory (SRAM) operable at a low voltage, there is a method in which a word-line selection-potential controller circuit is mounted on a chip to autonomously control a word-line selection potential.

### BRIEF DESCRIPTION OF THE DRAWINGS

FIG. 1 is a circuit diagram illustrating an SRAM memory cell and a voltage generation unit included in a cell-stability monitoring circuit.

FIG. 2 is a graph showing the correlations between the Vmgn and the SNM.

FIG. 3 is a graph showing the relationship between the value of the Vmgn and the process conditions or the temperature conditions.

FIG. 4 is a block diagram of a word-line selection-potential controller circuit that includes the cell-stability monitoring circuit.

FIG. 5 is a circuit diagram of a variable-selection-potential word-line driver.

FIG. 6 is a timing chart showing the waveforms related to the operations of the word-line selection-potential controller circuit.

FIG. 7 is a schematic diagram illustrating the overall configuration of a semiconductor device (semiconductor chip).

### DETAILED DESCRIPTION

For setting the word-line selection potential of an SRAM memory cell (hereinafter, simply referred to as a “memory cell”), a memory cell stability, a write characteristic, and a read speed need to be considered. More favorable memory cell stability is obtained with a lower word-line selection potential. In contrast, more favorable write characteristic is obtained with a higher word-line selection potential. More favorable read speed is obtained with a higher word-line selection potential. Note that the memory cell stability is a characteristic indicating the unlikelihood of disturb errors, and the write characteristic is a characteristic indicating the unlikelihood of writing errors.

The word-line selection potential must be set at an optimal value by taking account of these three factors. When the above-mentioned trade-off relations are taken into account, the two factors other than the memory cell stability prefer a higher word-line selection potential. For this reason, in this embodiment, only the memory cell stability is monitored and thereby the word-line selection potential is set at the highest level that satisfies desired memory cell stability. In this way, the write characteristic and the read speed can be each made as favorable as possible within a range that allows the necessary memory cell stability to be satisfied. Accordingly, it is possible to omit monitoring the write characteristic and the read speed. The setting of the optimal word-line selection potential in consideration of these trade-offs optimizes the balance among the memory cell stability, the write characteristic, and the read speed, and thereby allows the SRAM to operate at a lower voltage. The optimal word-line selection potential, however, changes because the above characteristics change depending on conditions such as the fluctuations in the characteristics due to the process variations, and the operational temperature of the chip. Hence, if the word-line selection potential is controlled to be an optimal potential depending on process variations and a chip temperature, the balance among the memory cell stability, the write characteristic, and the read speed can be always optimized, which enables the SRAM to operate at a lower voltage.

Static noise margin (SNM) is widely used as an indicator of the memory cell stability. The SNM is defined as the length of a side of the largest square inscribed in the area formed between the two curves of the input-output characteristics of the inverter pair included in the memory cell, where the input-output characteristics of the inverter pair under the settings of the word line and the bit-line pair at the high level are superposed one upon the other. The magnitude of the SNM can be used as an indicator of the memory cell stability, but it is difficult to measure the SNM in an on-chip circuit. Accordingly, in this embodiment, the Vmgn, which will be described later, is used as an indicator of the memory cell stability.

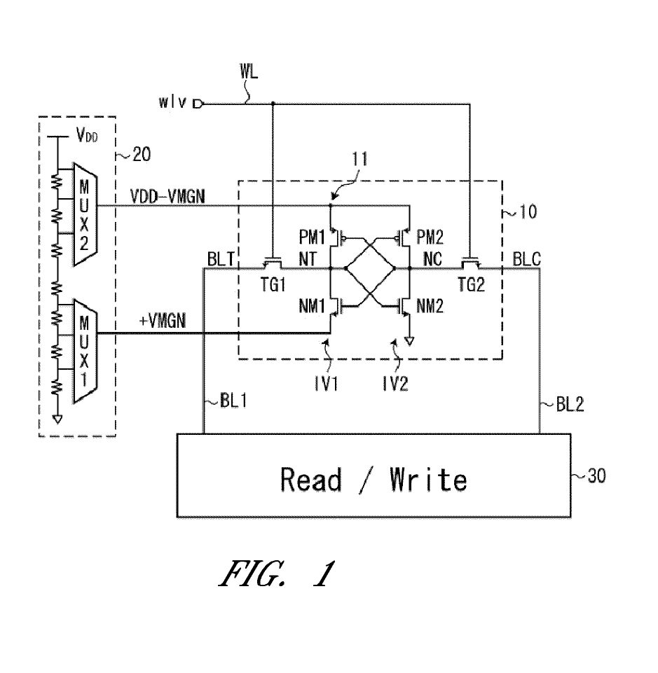

A cell-stability monitoring circuit of this embodiment is described below by referring to FIG. 1. FIG. 1 is a circuit diagram illustrating an SRAM memory cell, a voltage generation unit and an inversion detection unit included in the cell-stability monitoring circuit.

An SRAM memory cell 10 includes a first inverter IV1 and a second inverter IV2 which are connected to a single power-supply node 11 and are cross-coupled to each other. In addition, the SRAM memory cell 10 also includes a first transfer transistor TG1 and a second transfer transistor TG2. The first inverter IV1 includes a pMOS transistor PM1 connected to the power-supply node 11 and an nMOS transistor NM1. The second inverter IV2 includes a pMOS transistor PM2 connected to the power-supply node 11 and an nMOS transistor NM2. The input terminal of the first inverter IV1 is connected to the input terminal of the second inverter IV2 whereas the output terminal of the first inverter IV1 is connected to the output terminal of the second inverter IV2. The first transfer transistor TG1 is connected between the output terminal of the first inverter IV1 and a first bit line BL1. The gate of the first transfer transistor TG1 is connected to a word line WL. The second transfer transistor TG2 is connected between the output terminal of the second inverter IV2 and a second bit line BL2. The gate of the second transfer transistor TG2 is connected to the word line WL. The source terminal of the nMOS transistor NM1 included in the first inverter IV1 is connected to a first output terminal out1 of a voltage generation circuit 20. The power-supply node 11 is connected to a second output terminal out 2 of the voltage generation circuit 20.

The voltage generation circuit 20 includes plural resistors connected in series between a power-supply terminal Vdd and a ground terminal Vss. The voltages obtained by the resistive division by the plural resistors are selected by multiplexers MUX1 and MUX2, and are outputted to the first output terminal out1 and the second output terminal out2.

An inversion detection unit 30 is connected to the memory cell 10 via the first and second transfer transistors TG1 and TG2. If a word-line selection potential is applied to the word line WL with the memory cell 10 having data written therein, the inversion detection unit 30 detects whether or not the data written in the memory cell 10 is inverted. More details of the detection will be described later.

Next, with the configuration of FIG. 1, description will be given of a method of determining the word-line selection potential that satisfies desired memory cell stability. As described earlier, the SNM is a possible indicator of the memory cell stability, but the Vmgn, which has a correlation with the SNM, is measured as the indicator of the memory cell stability in this embodiment.

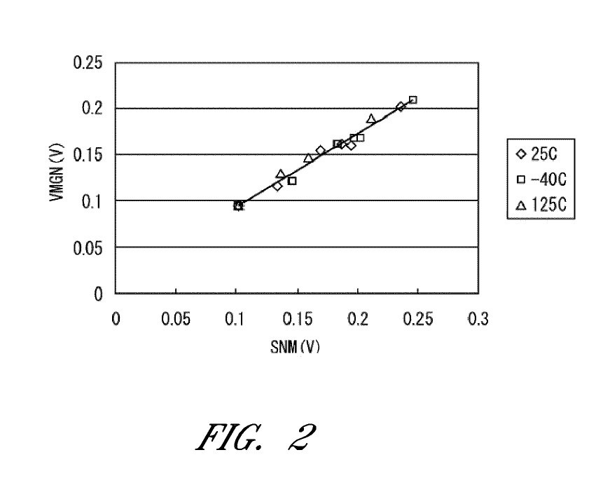

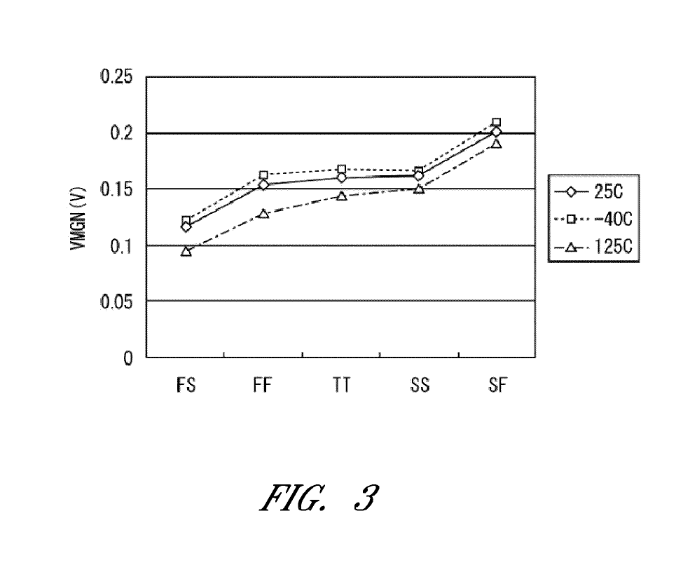

To begin with, description is given of the Vmgn, which is used as the indicator of the memory cell stability in this embodiment. With the memory cell shown in FIG. 1 having data written therein, a Vmgn is applied to the first output terminal out1 while a voltage Vdd-Vmgn, which is a lower voltage than a power-supply voltage Vdd by an amount equivalent to the Vmgn, is applied to the second output terminal out2. If, in this state, the Vmgn is raised up, the data written in the memory cell is inverted. The Vmgn at the time of the inversion is used as the indicator of the memory cell stability. The Vmgn has a strong correlation with the SNM, which is widely used as an indicator of the memory cell stability. FIG. 2 shows the correlation between the Vmgn and the SNM. FIG. 3 shows the relations among the value of the Vmgn, the process conditions, and the temperature conditions. Since the Vmgn and the SNM have a strong correlation as FIG. 2 shows, it is possible to determine, in advance, the Vmgn corresponding to the SNM that provides desired memory cell stability. In addition, as FIG. 3 shows, the changing of the Vmgn against the process conditions for the case of FF and the corresponding changing for the case of SS differ from each other. In addition, the changing of the Vmgn against the temperature varies depending upon the temperature conditions. Accordingly, in the case of the changing against either of the process conditions and the temperature, the changing of the SNM can be detected as the changing of the Vmgn. Note that, as for each symbol, for example, FS on the horizontal line in FIG. 3, the left side (F in this case) indicates a characteristic of the NMOS transistor, and the right side (S in this case) indicates a characteristic of the PMOS transistor. The same applies to the other symbols of “FF,” “SS,” and “SF.” Here, F (fast) indicates that a transistor is easily turned on, S (slow) indicates that a transistor is not easily turned on, and T (typical) indicates that a transistor has a characteristic as designed.

Next, description is given below of a method of determining the word-line selection potential by using the Vmgn determined in the above-described way.

In the configuration shown in FIG. 1, the voltage generation circuit 20 outputs the Vmgn to the first output terminal out1 and the Vdd-Vmgn to the second output terminal out2 by using the Vmgn determined in the above-described way. Then, data is written into the memory cell so that a node NT can be at the low level and a node NC can be at the high level. Then, the nodes BLT and BLC are pre-charged at the level Vdd, and a word-line selection potential Vwl is applied to the word line WL. At that moment, the inversion detection unit 30 detects whether or not the data written in the memory cell is inverted (from node NT: low level; node NC: high level to node NT: high level; node NC: low level). If the occurrence of the inversion of the data written in the memory cell means that the word-line selection potential Vwl applied to the word line is higher than the voltage (Vmgn) for the desired memory cell stability. Accordingly, if the data is inverted, the word-line selection potential Vwl to be applied to the word line is reduced. By repeating the above-described operations, the word-line selection potential that satisfies the desired memory cell stability is determined. Note that a fuse or the like may be used to make the Vmgn used in the voltage generation circuit 20 variable to set the optimal Vmgn. Note that both of the outputs from the terminals out1 and out2 voltage generation circuit 20 are changed in the description given above, but it is allowable that the output from the first output terminal out1 is fixed to the level Vdd and the output from the second output terminal out2 is made variable as the Vmgn.

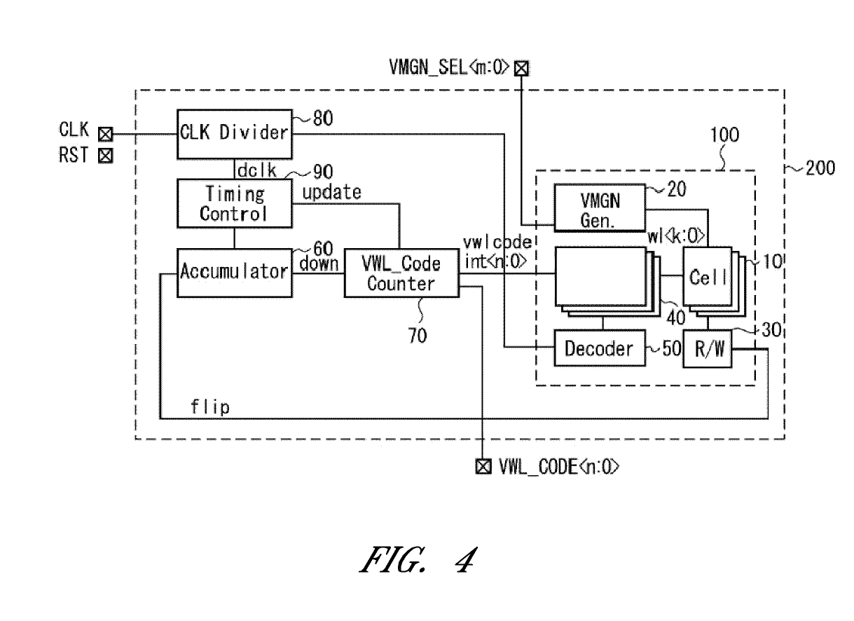

Next, description is given below of a cell-stability monitoring circuit by referring to FIG. 4. FIG. 4 is a block diagram illustrating a word-line selection-potential controller circuit including a cell-stability monitoring circuit.

A cell-stability monitoring circuit 100 includes the memory cell 10, the voltage generation circuit 20, and the inversion detection unit 30, all of which are shown in FIG. 1. In addition, the cell-stability monitoring circuit 100 also includes a variable-selection-potential word-line driver 40, and a decoder 50. The cell-stability monitoring circuit 100 includes plural memory cells 10 and plural variable-selection-potential word-line drivers 40 corresponding respectively to the plural memory cells.

A word-line selection-potential controller circuit 200 includes the cell-stability monitoring circuit 100, an accumulator circuit 60, a counter circuit 70, a CLK divider circuit 80, and a timing controller 90.

Each of the memory cells 10, the voltage generation circuit 20, and the inversion detection unit 30 included in the cell-stability monitoring circuit 100 operate in the above-described manner. Though the description is given by referring to FIG. 1 for a case where only a single memory cell 10 is included in the cell-stability monitoring circuit, plural memory cells are used to preclude the influence caused by the characteristic variations among the memory cells in the case shown in FIG. 4. Specifically, whether or not inversion occurs in each of the plural memory cells is firstly detected one by one, and then whether or not the word-line selection potential is to be decreased is detected by a determination whether or not the number of the inverted memory cells reaches a predetermined number.

Each of the variable-selection-potential word-line drivers 40 outputs the word-line selection potential to the word line of the corresponding memory cell 10 in accordance with a signal vwlcodeint from the counter circuit 70. Details of the counter circuit 70 and the signal vwlcodeint will be described later.

The decoder 50 outputs signals to select, from the plural memory cells, the one whose memory cell stability is to be monitored. The decoder 50 outputs the signals to the variable-selection-potential word-line drivers 40.

The inversion detection unit 30 detects whether or not inversion occurs in each of the memory cells one by one. If inversion occurs in the target memory cell, the inversion detection unit outputs a signal flip to the accumulator circuit 60. The accumulator circuit 60 counts the number of signals flip outputted by the inversion detection unit 30. The accumulator circuit 60 counts the number of the signals flip, and activates a signal down to reduce the word-line selection potential once the number of all the inverted memory cells 10 reaches a predetermined number.

In accordance with the signal down from the accumulator circuit 60, the counter circuit 70 outputs a digital signal vwlcodeint that designates the word-line selection potential to be outputted by the variable-selection-potential word-line driver 40. In addition, the counter circuit 70 outputs a signal VWL_CODE to the outside for the purpose of setting up, in the memory cells outside of the word-line selection-potential controller circuit, the word-line selection potential determined by the monitoring of the cell-stability monitoring circuit 100.

The CLK divider circuit 80 divides a system clock CLK inputted from the outside and thereby generates a slower clock dclk to be used in the word-line selection-potential controller circuit 200. Note that, instead of employing the CLK divider circuit 80 for the above-mentioned purpose, the word-line selection-potential controller circuit 200 may be configured to use the system clock CLK.

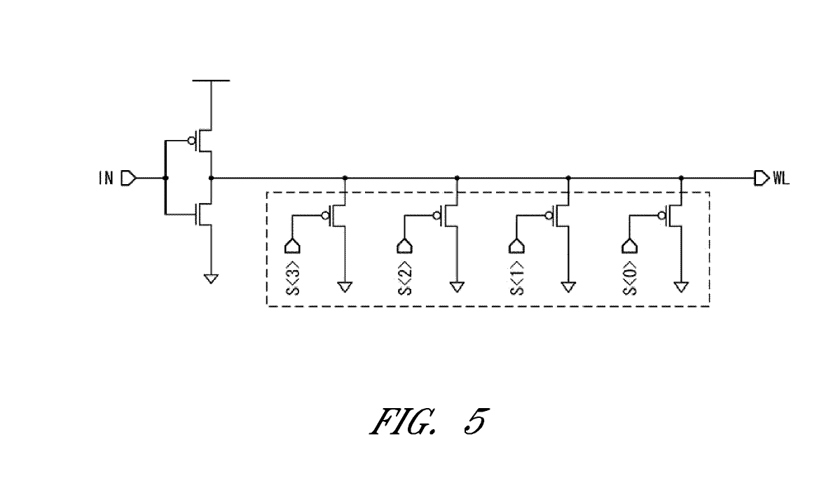

FIG. 5 illustrates each of the variable-selection-potential word-line drivers. The variable-selection-potential word-line driver 40 includes pull-down PMOS transistors, and digitally adjusts the word-line selection potential in accordance with the number of the PMOS transistors that are turned ON by the signal vwlcodeint from the counter circuit 70.

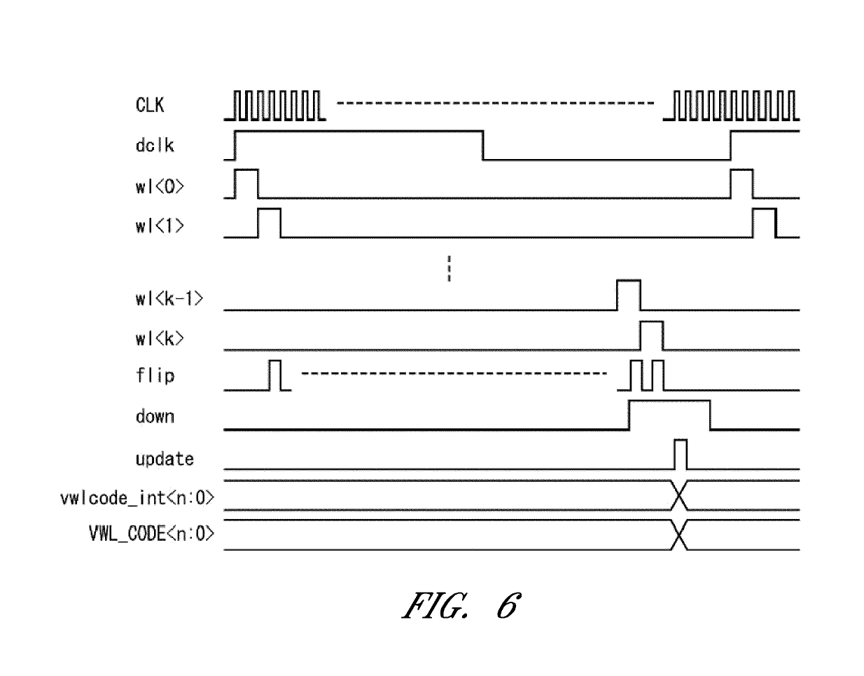

Next, the operations of the word-line selection-potential controller circuit 200 are described below by referring to FIG. 6. FIG. 6 is a timing chart showing various waveforms related to the operations of the word-line selection-potential controller circuit.

Firstly, a signal VMGN_SEL of the Vmgn that gives desired memory cell stability is inputted into the voltage generation circuit 20 from the outside. In accordance with the inputted signal VMGN_SEL, the voltage generation circuit 20 applies the Vmgn, which provides the desired memory cell stability, to the source terminal of the NMOS transistor included in the first inverter of each of the plural memory cells 10.

To select the memory cell to be monitored, the decoder 50 outputs signals, one after another, to designate the memory cells to the variable-selection-potential word-line driver 40. In accordance with the signals inputted from the decoder 50, the variable-selection-potential word-line driver 40 consecutively applies word-line selection potentials wl<0>, wl<1> . . . and wl<k> to the word lines WL of the memory cells 10 to be monitored.

The inversion detection unit 30 detects whether or not the data written in each of the memory cells 10 is inverted when the corresponding word-line selection potential is applied to the memory cell 10. If the data for the target memory cell 10 is inverted, the inversion detection unit 30 outputs a signal flip to the accumulator circuit 60.

The accumulator circuit 60 counts the number of the signals flip sent from the inversion detection unit 30. Once the number of all the memory cells 10 where inversion occurs reaches a predetermined number, the accumulator circuit 60 activates the signal down (i.e., outputs an “H”) to reduce the word-line selection potential.

Once the monitoring of all the memory cells is finished, the counter circuit 70 outputs a digital signal vwlcodeint and a digital signal VWL_CODE in response to a signal update sent from the timing controller 90. The digital signal vwlcodeint is outputted to the variable-selection-potential word-line driver 40 so as to designate the word-line selection potential to be outputted by the variable-selection-potential word-line driver 40. The digital signal VWL_CODE is outputted to the outside so as to designate the word-line selection potential to those memory cells outside of the word-line selection-potential controller circuit.

As has been described above, the word-line selection potential is determined by monitoring the plural memory cells, and furthermore plural memory cells can be monitored by using the word-line selection potential thus determined. Accordingly, the word-line selection potential can be determined to be the highest potential that satisfies desired memory cell stability. In addition, the use of the word-line selection potential determined by the word-line selection-potential controller circuit 200 to set in the memory cells outside of the word-line selection-potential controller circuit 200 (i.e., the memory cells used as ordinary SRAM memory cells) allows the use of the optimal word-line selection potential.

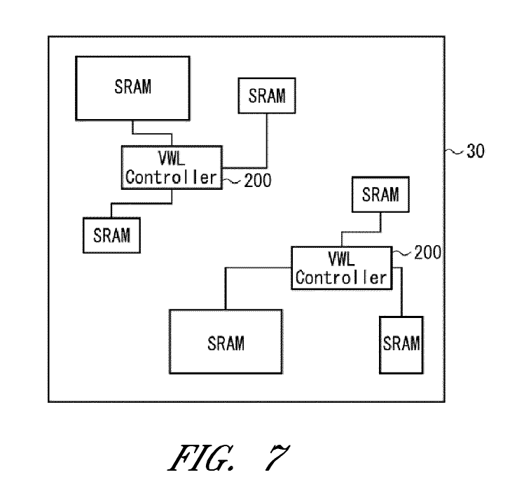

Next, the overall configuration of a semiconductor device including the word-line selection-potential controller circuit 200 is described by referring to FIG. 7. FIG. 7 is a schematic diagram illustrating the overall configuration of the semiconductor device (semiconductor chip).

Plural SRAM blocks are distributed on a semiconductor chip 300. In this embodiment, plural units of the above-described word-line selection-potential controller circuit 200 are distributed on the semiconductor chip 300. Each word-line selection-potential controller circuit 200 determines the word-line selection potential corresponding to the temperature that differs from one place to another within the semiconductor chip. The word-line selection potential thus determined by each word-line selection-potential controller circuit 200 is set in the SRAM blocks located therearound. In addition, each word-line selection-potential controller circuit 200 can reflect the process conditions within the semiconductor chip in the word-line selection potential.

As has been described thus far, each word-line selection-potential controller circuit 200 monitors the memory cell stability and thereby determines the word-line selection potential. Thus, the SRAM can be operated at a low voltage.

Note that the embodiment described above is provided only for the purpose of facilitating the understanding of the invention. The embodiment is not provided for the purpose of limiting the interpretation of the invention. Various modifications and improvements can be made without departing from the scope of the invention, and the invention includes the equivalents.

What is claimed is:

1. A semiconductor device comprising:
an SRAM memory cell including:
a first inverter and a second inverter that are cross-coupled to each other;
a first transfer transistor connected between an output terminal of the first inverter and a first bit line, and including a gate connected to a word line; and
a second transfer transistor connected between an output terminal of the second inverter and a second bit line, and including a gate connected to the word line;
a voltage generation unit configured to apply a predetermined voltage to a source terminal of an NMOS transistor included in the first inverter;
an inversion detection unit connected to the SRAM memory cell via the first and the second transfer transistors, and configured to detect whether or not inversion of data written in the SRAM memory cell occurs when a word-line selection potential is applied to the word line with the SRAM memory cell having the data written therein; and
a word-line selection-potential determination unit configured to control the word-line selection potential to be applied to the word line in accordance with a detection result of the inversion detection unit.

2. The semiconductor device according to claim 1 wherein
the word-line selection-potential determination unit perform control to set the word-line selection potential at the highest one of voltages that satisfy cell stability of the SRAM memory cell.

3. The semiconductor device according to claim 2 wherein
a plurality of the SRAM memory cells are provided in the semiconductor device,
the inversion detection unit detects whether or not inversion of the data written in each of the plurality of the SRAM memory cells occurs when a common word-line selection potential is applied to the plurality of SRAM memory cells, and
if a predetermined number or more of the SRAM memory cells have data inversion, the word-line selection-potential determination unit controls the word-line selection potential to be applied to the word line.

4. The semiconductor device according to claim 3 wherein
if a predetermined number or more of the SRAM memory cells have data inversion, the word-line selection-potential determination unit lowers the word-line selection potential.

5. The semiconductor device according to claim 4 wherein
a plurality of the SRAM memory cells, a plurality of the voltage generation units, a plurality of the inversion detection units and a plurality of the word-line selection-potential determination unit are arranged dispersedly on a semiconductor chip, and
the word-line selection potential determined by each of the word-line selection-potential determination units is used as the word-line selection potential for SRAMs located around the each word-line selection-potential determination unit.
